(19) United States
(12) Patent Application Publication
(10) Pub. No.: US 2016/0120050 A1
(43) Pub. Date: Apr. 28, 2016

(54) MULTI-DIRECTIONAL DISPLAY DEVICE

(71) Applicant: Penetek Technology, Inc., New Taipei City (TW)

(72) Inventor: Tsung-Lung CHEN, Taipei City (TW)

(21) Appl. No.: 14/523,262

(22) Filed: Oct. 24, 2014

(51) Int. Cl. H05K 5/02; H05K 5/00

(52) U.S. Cl. CPC H05K 5/0234; H05K 5/0204; H05K 5/0017

(57) ABSTRACT

A multi-directional display device includes a base body, a support frame, and a display module. The base body includes a first rotatable module. The support frame is movably disposed on the base body via the first rotatable module. The support frame has a first viewable position and a second viewable position. The support frame is rotatable between the first and the second viewable position. The support frame includes a second rotatable module. The display module is rotatably disposed on the support frame via the second rotatable module. When the support frame rotates between the first and the second viewing positions, the display module is rotatable on the support frame and a display surface of the display module faces outward with respect to the base body.

### BACKGROUND OF THE INVENTION

1. Field of the Invention

The instant disclosure relates to a multi-directional display device; in particular, to a multi-directional display device having two rotatable modules to provide front to back flipping and rotation for the display device at the display center thereof.

2. Description of Related Art

Although current display devices allow for displace interfaces to rotate according to a user's viewing angle, however, the rotation is limited to only the left and right directions and cannot provide front to back flipping and vise versa, as well as rotation about the display center of the display device, which leads to inconvenience.

Typically, more than half of the display devices on POS systems that businesses use are physically fixed or stationary. If a customer has inquiries regarding product details, staff members oftentimes cannot rotate the display device for customer viewing. Alternatively, businesses may use a touch screen to provide customers with on the spot product selection. However, since the conventional display device is typically fixed, staff members again cannot rotate the display device for customer selection or even viewing. As a result, businesses might need to purchase additional equipment or touch screen displays that can cause inconvenience and add excess costs.

Moreover, since conventional fixed display devices typically cannot rotate, the overall dimension of length, width or height is fixed. As a result, the relative placement of the display device on a counter or store is highly based on the overall dimension of the display device. In other words, the user cannot appropriately adjust the dimensions of the display device according to the limited space available, which can cause inconvenience and problems as mentioned above.

To address the above issues, the inventor strives via associated experience and research to present the instant disclosure, which can effectively improve the limitation described above.

### SUMMARY OF THE INVENTION

The objective of the instant disclosure is to provide a multi-directional display device that can provide angle or directional adjustments to resolve the problems of the conventional arts.

In order to achieve the aforementioned objectives, according to an embodiment of the instant disclosure, a multi-directional display device is provided. The multi-directional display device includes a base body, a support frame, and a display module. The support frame is movably disposed on the base body via the first rotatable module. The support frame has a first viewable position and a second viewable position. The support frame is rotatable between the first and the second viewable position. The support frame includes a second rotatable module. The display module is rotatably disposed on the support frame via the second rotatable module. When the support frame rotates between the first and the second viewing positions, the display module is rotatable on the support frame and a display surface of the display module faces outward with respect to the base body.

The instant disclosure provides improvements such as: the position of the display module can be adjusted according to the difference in position between the user and the base body by adjusting the support frame of the display module between the first viewing position and the second viewing position. Moreover, the display module can be adjusted to a vertical viewing mode or a horizontal viewing mode via the second rotatable module. In summary, the multi-directional display device of the instant disclosure can effectively adjust the position and direction of the display module via the first and the second rotatable modules. Moreover, with the first and second rotatable modules, the overall width and height of the display device can be adjusted to align with the space available.

In order to further understand the instant disclosure, the following embodiments and illustrations are provided. However, the detailed description and drawings are merely illustrative of the disclosure, rather than limiting the scope being defined by the appended claims and equivalents thereof.

### BRIEF DESCRIPTION OF THE DRAWINGS

FIG. 1 is an exploded view of a multi-directional display device in accordance with the instant disclosure;

FIG. 2 is a perspective view illustrating a support frame of the multi-directional display device at a first viewing position in accordance with the instant disclosure;

FIG. 3 is a side view of FIG. 2;

FIG. 4 is a perspective view illustrating the support frame of the multi-directional display device at a second viewing position in accordance with the instant disclosure;

FIG. 5 is a side view of FIG. 4;

FIG. 6 is a perspective view illustrating the support frame of the multi-directional display device at the first viewing position and a display module at an upright position in accordance with the instant disclosure;

FIG. 7 is a side view of FIG. 6;

FIG. 8 is a perspective view illustrating the support frame of the multi-directional display device at the second viewing position; and

FIG. 9 is a side view of FIG. 8.

### DETAILED DESCRIPTION OF THE PREFERRED EMBODIMENTS

The aforementioned illustrations and detailed descriptions are exemplary for the purpose of further explaining the scope of the instant disclosure. Other objectives and advantages related to the instant disclosure will be illustrated in the subsequent descriptions and appended drawings.

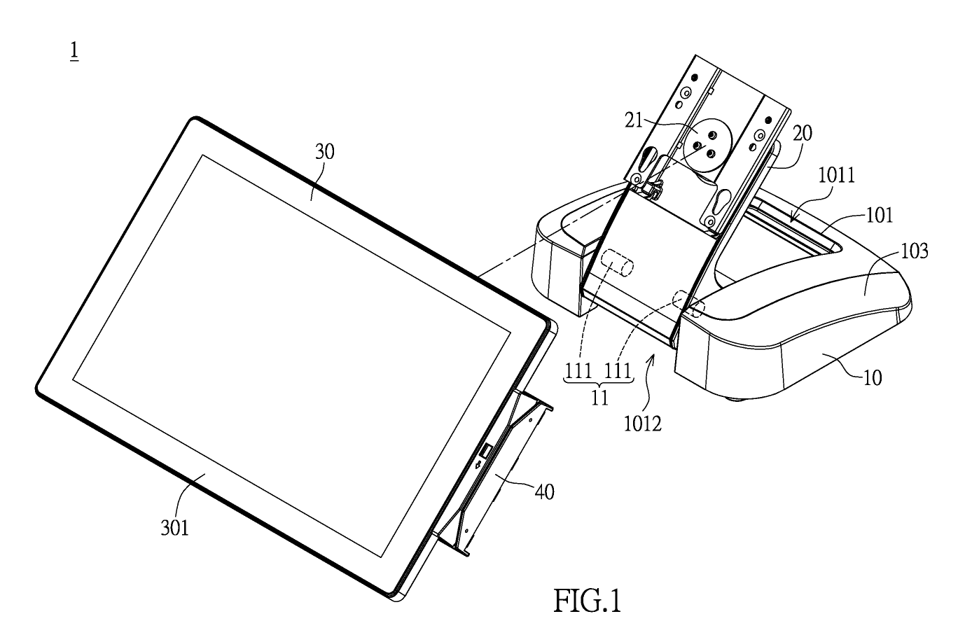

Please refer to FIGS. 1 to 3 as schematic diagrams illustrating a multi-directional display device in accordance with the instant disclosure. The display device 1 includes a base body 10, a support frame 20, and a display module 30. The base body 10 includes a first rotatable module 11 and the support frame 20 includes a second rotatable module 21. The support frame 20 can be movably disposed on the base body 10 via the first rotatable module 11 and the display module 30 can be movably disposed on the support frame 20 via the second rotatable module 21. The display module 30 can be a touch screen (or a typical display screen). At least one side of the display module 30 can have at least one input module 40, such as a card reader as shown in figures, arranged thereon.

The base body 10 has a receiving slot 101. The receiving slot 101 has a close end 1011 and an open end 1012. The first rotatable module 11 is correspondingly installed at the open end 1012. The first rotatable module 11 can include two rotatable units 111 that can be respectively arranged on two corresponding sides of the base body 10 proximate to the open end 1012. Preferably, each rotatable unit 111 can be a multi-sectional rotatable structure that can rotate and stop at a position as necessary, so that users can turn, stop, and maintain the support frame 20 at a position of a certain angle. The second rotatable module 21 can also be a multi-sectional rotatable structure.

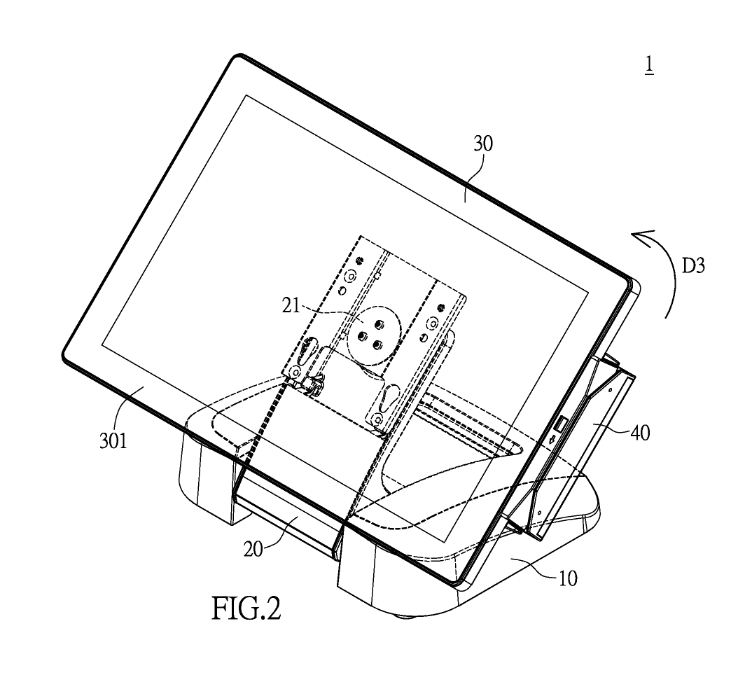

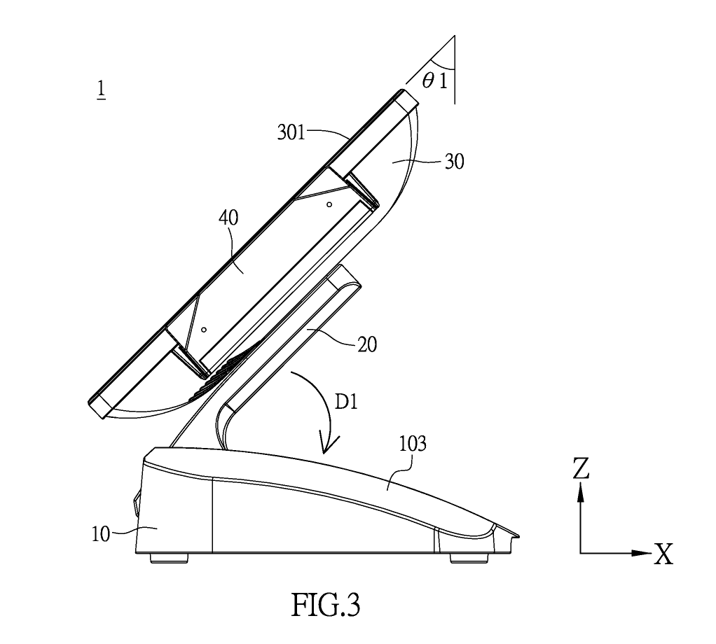

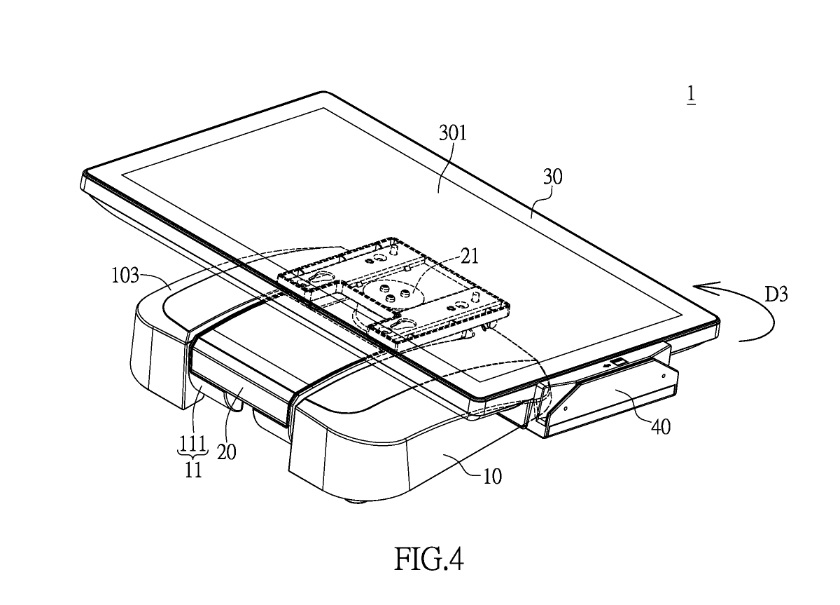

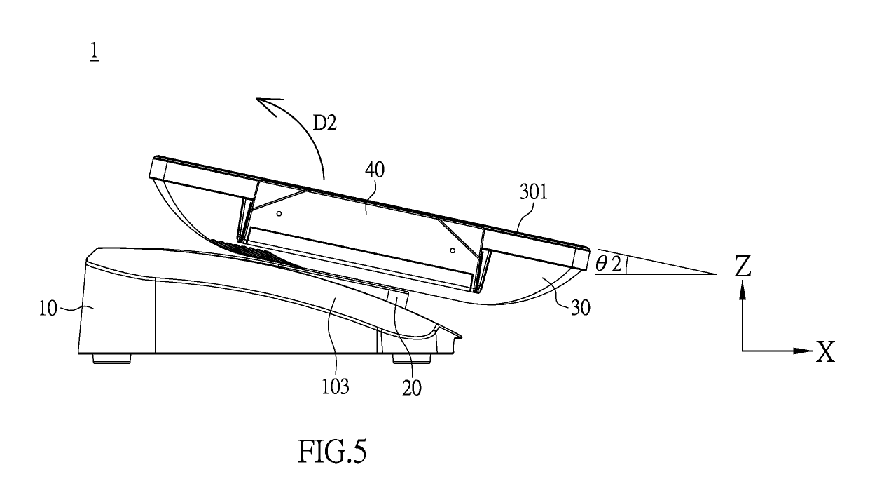

Please refer to FIGS. 2 to 5. The display support frame 20 can rotate towards a first direction D1 or a second direction D2 via the first rotatable module 11, such that the support frame 20 can rotate from a first viewing position (as shown in FIGS. 2 and 3) to a second viewing position (as shown in FIGS. 4 and 5) and maintain at a position therebetween. Users can then adjust the direction in which the display surface 301 of the display module 30 faces. As the support frame 20 is being rotated, the display surface 301 of the display module 30 faces outwards with respect to the base body 10. In other words, the display surface 301 can be seen by the user no matter where the support frame is being rotated, at the first viewing position, the second viewing position, or a position between the two viewing positions. For example, the display module 30, such a touch screen, can be controlled by a user no matter what position the support frame 20 is being turned to.

As shown in FIG. 3, the support frame 20 is at a first viewing position 20. The display module 30 (or the support frame 20) can be pressed so that the display module 30 and the support frame 20 rotates in the first direction D1 (rotates along the X-axis direction as shown in figures), which changes an angle θ2 between the support frame 20 and a horizontal axis as well as an angle θ1 between the display surface 301 and a vertical axis, and the display surface aligns with a user's viewing angle. Similarly, when the support frame 20 is at the second viewing position as shown in FIG. 5, the display module 30 can be rotated in the second direction D2, opposite to the first direction D1, in order to change the angle θ2 between the display surface 301 and the horizontal axis via the first rotatable module 11. In a preferred embodiment, the angle θ1 between the display surface 301 and the vertical axis when the support frame 20 is in the first viewing position is larger than the angle θ2 between the display surface 301 and the horizontal axis when the support frame 20 is in the second viewing position.

In other words, the user can rotate the display surface 301 from a direction opposite to the X axis arrow as shown in FIG. 3 (when the support frame 20 is at the first viewing position) to the direction of the X axis arrow as shown in FIG. 5 (when the support frame 20 is at the second viewing position) via the first rotatable module 11. With the first rotatable module 11, the display surface 301 of the display module 30 can rotate approximately 180 degrees (the actual rotatable angle can be adjusted as necessary and is not limited thereto), or alternatively, the display module 30 can be flipped forward and/or backward via the first rotatable module 1.

The display module 30 can further include a gyroscope arranged therein for detecting the position of the display module 30 after rotation and correspondingly adjusting the orientation of the image on the display module 30. For example, when a cashier prefers to show data on the display module 30 to a customer, the display module 30 of the display device 1 on a cash register can be rotated to face towards a customer via the first rotatable module 11. Alternatively, the cashier can configure the display surface 301 to face upward, so more than one person can simultaneously view the content shown on the display module 30.

Moreover, with the first rotatable module 11, the overall height of the display device 1 can be adjusted to match that of the user, such as the relatively higher positioning as shown in FIG. 3 or the relatively lower positioning as shown in FIG. 5.

Furthermore, when the display module 30 is at the first viewing position, an auxiliary display module (not shown in figures) can be movably arranged on a side opposite to the display module 30 (along the direction of the X-axis as shown in figures) for convenience. Specifically, when the display module 30 is not in use by the user, the auxiliary display module can be used for searches of product information.

Notably, in order to provide users with the most preferred viewing angle, the angle θ1 between the display surface 301 and the vertical axis is preferably an acute angle when the support frame 20 is at the first viewing position, and the angle θ2 between the display surface 301 and the horizontal axis is also preferably an acute angle when the support frame 20 is at the second viewing position as shown in FIGS. 3 and 5. Specifically, when the support frame 20 is at the second viewing position, at least one portion of the support frame 20 can be correspondingly received in the receiving slot 101 to prevent physical interference between the support frame 20 and the base body 10. As a result, the display surface 301 is closer to the base body 10, thus, the angle θ2 between the display surface 301 and the horizontal axis is relatively smaller, which provides for better viewing angles.

Moreover, in the most preferred embodiment, the receiving slot 101 can have arranged therein at least one cushioning member (not shown in figures). When portions of the support frame 20 are arranged in the receiving slot 101, the support frame 20 abuts the cushioning member to prevent direct contact between the support frame 20 and the receiving slot 101 or damage if improperly handled.

As shown in FIGS. 4 and 5, when the support frame 20 is at the second viewing position, in addition to the first rotatable module 11, the angle θ2 between the display surface 301 and the horizontal axis can also be adjusted by the overall shape of the base body 10. Specifically, the base body 10 can further include a slanted surface 103 arranged proximate to the receiving slot 101. When the support frame 20 is at the second viewing position, portions of the support frame 20 are received in the receiving slot 101 and at least one portion of the display module 30 facing the base body 10 presses on the slanted surface 103. With the slanted surface 103, the display module 30 is limited and cannot rotate towards the direction of the base body 10 (the first direction D1), which can provide adjustments to and restrain to the angle θ2 between the display surface 301 and the horizontal axis, such that the display module 30 can be placed at the most preferred viewing angle possible.

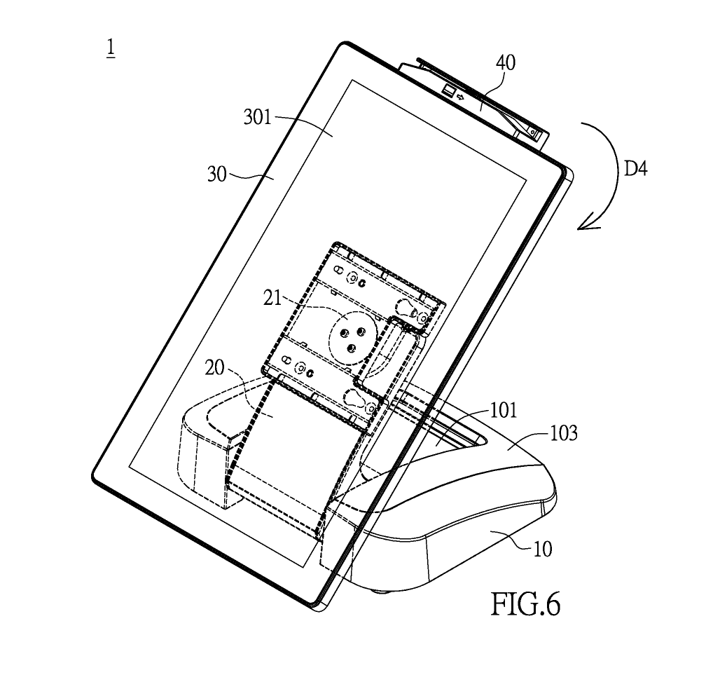

Please refer to FIG. 2. The display module 30 can rotate towards the third direction D3 via the second rotatable module 21, such that the display module 30 is as shown in FIG. 6. The display module 30 can be rotated to adjust the position of the display surface 301 via the second rotatable module 21. Specifically, the display module 30 can be arranged in a horizontal mode via the second rotatable module 21 or be adjusted to a vertical mode as shown in FIG. 6. When the display module 30 is in the mode as shown in FIG. 6, the display module 30 can rotate towards a direction D4, opposite to the third direction D3, via the second rotatable module 21 in order to change the mode of the display module 30.

With the second rotatable module 21, the display module 30 as shown in FIG. 2 can be adjusted to the mode as shown in FIG. 6 and can provide the overall display device 1 with a larger width. The overall width of the display device 1 can be adjusted according to the actual usable space for the display device 1 via the second rotatable module 21. Alternatively, the height at which the display device 1 is positioned can be adjusted to a relatively higher position (as shown in FIG. 6) or a relatively lower position (as shown in FIG. 2) by the second rotatable module 21. In a preferred embodiment, the relatively shorter side of the display module 30 has a length, and the value of the length is identical to that of a width of the base body 10.

In an even more preferred embodiment, the display module 30 can be arranged with a gyroscope therein. When the user prefers to change the display mode of the displayed imaging on the display module 30 (the horizontal mode as shown in FIG. 2), the display module 30 can be rotated via the second rotatable module 21, and the displayed imaging can be adjusted from the horizontal mode as shown in FIG. 2 to the vertical mode as shown in FIG. 3 via the detection of the gyroscope.

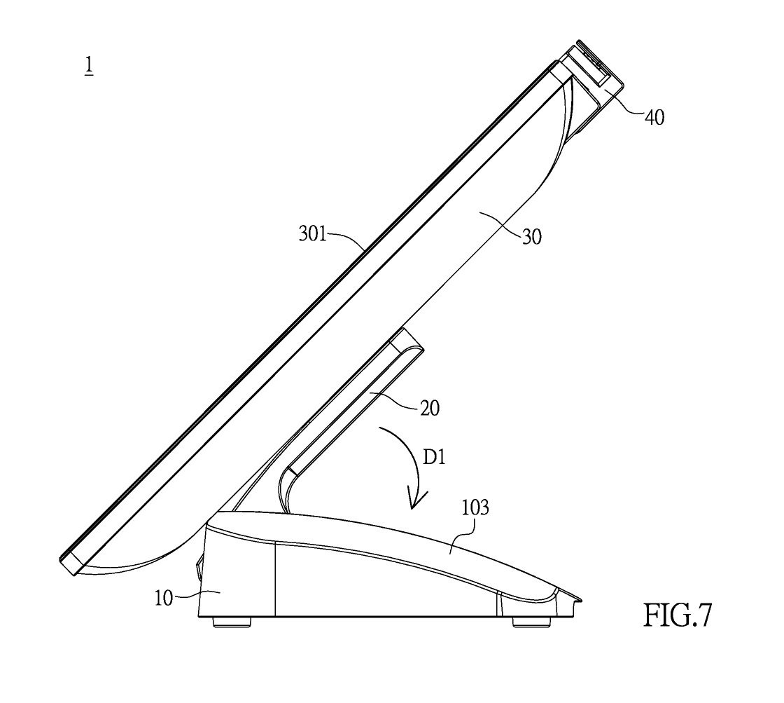

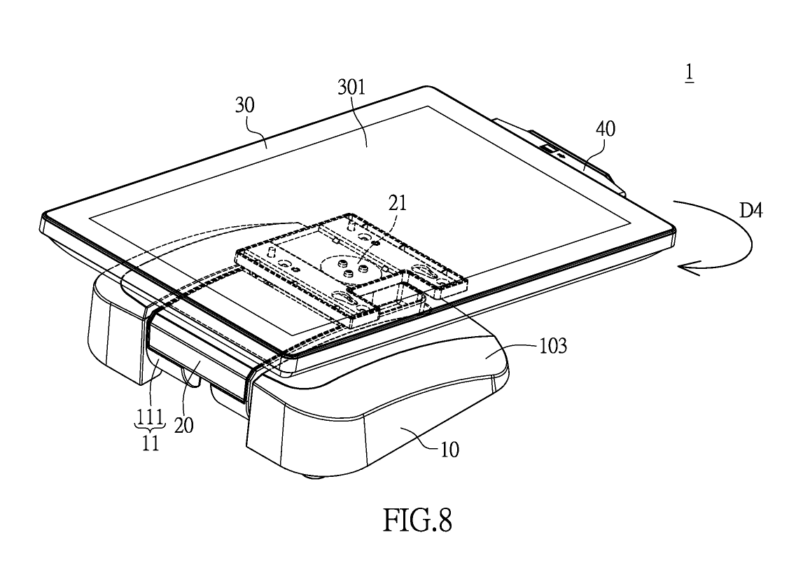

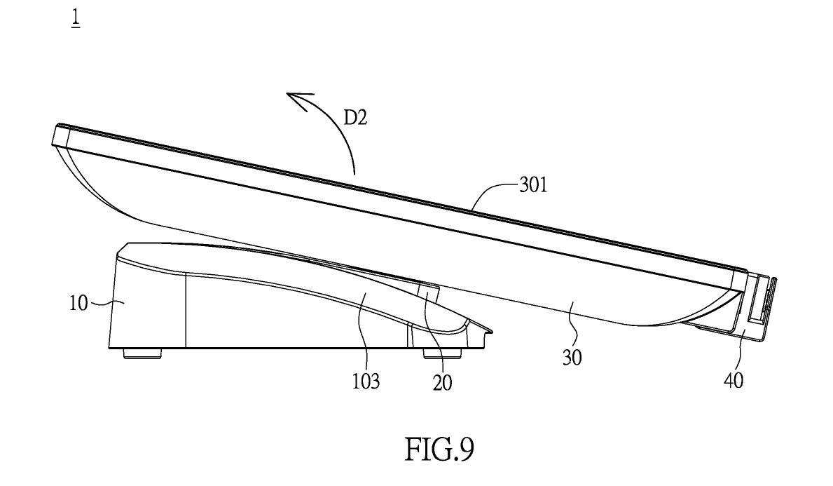

Please refer to FIGS. 6 to 9. When the display module 30 resembles the modes as shown in FIGS. 6 and 7, the support frame 20 can be rotated towards the first direction D1 from the first viewing position to the second viewing position as shown in FIGS. 8 and 9 via the first rotatable module 11. Relatively, the display module 30 can be rotated towards the second direction D2 via the first rotatable module 11 as shown in FIGS. 8 and 9. Specifically, the first rotatable module 11 and the second rotatable module 21 can be two independent structures. Users can simultaneously apply the two rotatable modules 11 and 21. In other words, the angle between the display module 30 and horizontal axis can be adjusted via the first rotatable module 11 while the display module 30 can be rotated via the second rotatable module 21. As a result, the position of the display module 30 can be adjusted as necessary to align with the user's viewing angle.

The figures and descriptions supra set forth illustrate the preferred embodiments of the instant disclosure; however, the characteristics of the instant disclosure are by no means restricted thereto. All changes, alterations, combinations or modifications conveniently considered by those skilled in the art are deemed to be encompassed within the scope of the instant disclosure delineated by the following claims.

What is claimed is:

1. A multi-directional display device, comprising:
a base body including a first rotatable module;
a support frame movably disposed on the base body via the first rotatable module, the support frame having a first viewable position and a second viewable position, and the support frame having a second rotatable module disposed thereon; wherein the support frame is rotatable between the first and the second viewable positions via the first rotatable module; and
a display module rotatably disposed on the support frame via the second rotatable module, and the display module having a display surface;
wherein when the support frame rotates between the first and the second viewing positions, the display module is rotatable on the support frame; and wherein the display surface of the display module faces outward with respect to the base body.

2. The multi-directional display device as recited in claim 1, wherein the support frame is rotatable in a first direction and a second direction opposite to the first direction via the first rotatable module, the display module is rotatable in a third direction and a fourth direction opposite to the third direction; and wherein the first direction and second direction are in a different rotational plane with respect to the third direction and the fourth direction.

3. The multi-directional display device as recited in claim 2, wherein the base body includes a receiving slot, and when the support frame is in the second viewing position, at least one portion of the support frame is arranged in the receiving slot.

4. The multi-directional display device as recited in claim 3, wherein the base body includes a slanted surface, when the support frame is in the second viewing position, at least one portion of the display module abuts the slanted surface.

5. The multi-directional display device as recited in claim 4, wherein when the support frame is in the first viewing position, the display surface and a vertical axis define an acute angle therebetween, and when the support frame is in the second viewing position, the display surface and a horizontal axis define another acute angle therebetween.

6. The multi-directional display device as recited in claim 5, wherein the angle between the display surface and the vertical axis when the support frame is in the first viewing position is larger than the angle between the display surface and the horizontal axis when the support frame is in the second viewing position.

7. The multi-directional display device as recited in claim 6 further comprising:
an auxiliary display module; wherein when the support frame is in the first viewing position, the auxiliary display module is disposed on a side of the support frame and is arranged opposite the display module.

8. The multi-directional display device as recited in claim 7, wherein the receiving slot has at least one cushioning member arranged therein, and when the support frame is received in the receiving slot, the support frame abuts the at least one cushioning member.

9. The multi-directional display device as recited in claim 8, wherein the display module includes a gyroscope to detect a position of the display module after the display module and the support frame rotate with respect to the second rotatable module.

10. The multi-directional display device as recited in claim 9, wherein the display module has a side relatively shorter than the other sides thereof, the short side has a length, the base body has a width, and the length has a value identical to a value of the width.
